(19) United States
(12) Patent Application Publication
(10) Pub. No.: US 2021/0350107 A1
(43) Pub. Date: Nov. 11, 2021

(54) Apparatus for Capturing Fingerprint and Electronic Equipment

(71) Applicant: Shanghai Harvest Intelligence Technology Co., Ltd., Shanghai (CN)

(72) Inventor: Ya Hsiang TAI, Shanghai (CN)

(73) Assignee: Shanghai Harvest Intelligence Technology Co., Ltd., Shanghai (CN)

(21) Appl. No.: 17/314,985

(22) Filed: May 7, 2021

(30) Foreign Application Priority Data
May 7, 2020 (CN) 202020733566.6
May 7, 2020 (CN) 202020733576.X

(51) Int. Cl. G06K 9/00; H03K 19/20

(52) U.S. Cl. CPC G06K 9/00013; H03K 19/20

(57) ABSTRACT

The present disclosure provides an apparatus for capturing a fingerprint and an electronic equipment. The apparatus includes: a sensor array, corresponding to a plurality of fingerprint detection areas, wherein each fingerprint detection area corresponds to a plurality of sensors in the sensor array; an area detection circuit, configured to detect a fingerprint detection area where the fingerprint is located; and a fingerprint scanning circuit, configured to scan sensors corresponding to a preset fingerprint detection area based on a detection result of the area detection circuit, wherein the preset fingerprint detection area comprises the fingerprint detection area where the fingerprint is located. With solutions of the present disclosure, a power consumption of the apparatus can be reduced.

### CROSS-REFERENCE TO RELATED APPLICATIONS

The present application claims the benefit of priority to Chinese patent application No. 202020733576.X, filed on May 7, 2020, entitled “Apparatus for Capturing Fingerprint and Electronic Equipment”, the entire disclosures of which are incorporated herein by reference.

The present application claims the benefit of priority to Chinese patent application No. 202020733566.6, filed on May 7, 2020, entitled “Apparatus for Capturing Fingerprint and Electronic Equipment”, the entire disclosures of which are incorporated herein by reference.

### TECHNICAL FIELD

The present disclosure relates to the technical field of fingerprint identification, and more particularly to an apparatus for capturing a fingerprint and electronic equipment.

### BACKGROUND

With development of information technology, biometric identification technology is playing an increasingly important role in ensuring information security. Fingerprint identification has become one of key technical means for identity identification and device unlocking widely used in the field of mobile internet.

During fingerprint identification, a fingerprint needs to be scanned first to collect corresponding fingerprint information, and then a fingerprint image is formed. The fingerprint image is identified to confirm a user's identity or unlock the device.

In existing apparatus for fingerprint capturing, when the fingerprint is scanned, the sensor array in the apparatus is usually scanned in a full array, which results in a high-power consumption of the apparatus for fingerprint capturing.

### SUMMARY

Embodiments of the present disclosure provide an apparatus for fingerprint capturing, which can reduce power consumption of the apparatus for fingerprint capturing.

An embodiment of the present disclosure provides an apparatus for capturing a fingerprint. The apparatus includes: a sensor array, corresponding to a plurality of fingerprint detection areas, wherein each fingerprint detection area corresponds to a plurality of sensors in the sensor array; an area detection circuit, configured to detect a fingerprint detection area where the fingerprint is located; and a fingerprint scanning circuit, configured to scan sensors corresponding to a preset fingerprint detection area based on a detection result of the area detection circuit, wherein the preset fingerprint detection area includes the fingerprint detection area where the fingerprint is located.

In some embodiment, the preset fingerprint detection area further includes an adjacent fingerprint detection area adjacent to the fingerprint detection area where the fingerprint is located, and the adjacent fingerprint detection area includes all fingerprint detection areas adjacent to the fingerprint detection area where the fingerprint is located, or a part of the all fingerprint detection areas adjacent to the fingerprint detection area where the fingerprint is located.

In some embodiment, the fingerprint scanning circuit includes a plurality of fingerprint scanning subcircuits corresponding to the plurality of fingerprint detection areas respectively, and each fingerprint scanning subcircuit is configured to scan sensors corresponding to a fingerprint detection area corresponding to the each fingerprint scanning sub circuit.

In some embodiment, each fingerprint detection area corresponds to one or more rows of sensors in the sensor array, and each fingerprint scanning subcircuit is coupled with the one or more rows of sensors in the sensor array through a scanning line to scan the one or more rows of sensors in the sensor array.

In some embodiment, in the fingerprint scanning circuit, one or more fingerprint scanning subcircuits corresponding to the preset fingerprint detection area are configured to scan corresponding sensors in the sensor array in a time division manner, and other fingerprint scanning subcircuits are configured to reset remaining sensors in the sensor array.

In some embodiment, the plurality of fingerprint scanning subcircuits includes a first fingerprint scanning subcircuit and a second fingerprint scanning subcircuit, the first fingerprint scanning subcircuit is configured to scan sensors corresponding to a first fingerprint detection area, and the second fingerprint scanning subcircuit is configured to scan sensors corresponding to a remaining fingerprint detection area other than the first fingerprint detection area, wherein the sensors corresponding to the first fingerprint detection area includes a first row of sensors in the sensor array.

In some embodiment, the first fingerprint scanning subcircuit includes: a first NAND gate circuit, a first inverter, a second inverter, 2N numbers of second NAND gate circuits, N numbers of third NAND gate circuits and a first shift register, wherein N is the number of rows of the sensor scanned by the first fingerprint scanning subcircuit. A first input end of the first NAND gate circuit is coupled with a signal output end of a corresponding fingerprint detection area, a second input end of the first NAND gate circuit is coupled with a scanning enable signal output end, and an output end of the first NAND gate circuit is coupled with an input end of the first inverter. An output end of the first inverter is coupled with an input end of the first shift register. An input end of the second inverter is coupled with the first input end of the first NAND gate circuit, an output end of the second inverter is coupled with a second NAND gate circuit at an odd position among the 2N numbers of second NAND gate circuits, and an input end of the second NAND gate circuit at the odd position among the 2N numbers of second NAND gate circuit is coupled with the scanning enable signal output end. An input end of a second NAND gate circuit at an even position among the 2N numbers of second NAND gate circuits is coupled with a corresponding output end of the first shift register, and another input end of the second NAND gate circuit at the even position among the 2N numbers of second NAND gate circuits is coupled with the first input end of the first NAND gate circuit. An input end of a third NAND gate circuit is coupled with output ends of two second NAND gate circuits adjacent to the third NAND gate circuit, wherein the N numbers of third NAND gate circuits are coupled with different second NAND gate circuits, and an output end of the third NAND gate circuit is coupled with a corresponding row of sensors through a scanning line.

In some embodiment, the second fingerprint scanning subcircuit includes a fourth NAND gate circuit, a fifth NAND gate circuit, a sixth NAND gate circuit, a seventh NAND gate circuit, a second shift register, a third inverter, a first NOR gate circuit, and 2K numbers of eighth NAND gate circuits and K numbers of ninth NAND gate circuits, wherein K is the number of rows of sensors scanned by the second fingerprint scanning sub circuit. A first input end of the fourth NAND gate circuit is coupled with a signal output end of a corresponding fingerprint detection area, a second input end of the fourth NAND gate circuit is coupled with the scanning enable signal output end, and an output end of the fourth NAND gate circuit is coupled with an input end of the sixth NAND gate circuit. An input end of the fifth NAND gate circuit is coupled with an output end of a shift register in a previous fingerprint scanning subcircuit adjacent to the second fingerprint scanning subcircuit, and another input end of the fifth NAND gate circuit is coupled with a signal output end of a fingerprint detection area corresponding to the previous fingerprint scanning subcircuit. Another input end of the sixth NAND gate circuit is coupled with an output end of the fifth NAND gate circuit, and an output end of the sixth NAND gate circuit is coupled with an input end of the second shift register. A first input end of the first NOR gate circuit is coupled with the previous fingerprint scanning subcircuit, a second input end of the first NOR gate circuit is coupled with an input end of the third inverter, and an output end of the first NOR gate circuit is coupled with an eighth NAND gate circuit at an odd position among the 2K numbers of eighth NAND gate circuits. An input end of the eighth NAND gate circuit at the odd position among the 2K numbers of eighth NAND gate circuits is coupled with the scanning enable signal output end. An output end of the third inverter is coupled with an input end of the seventh NAND gate circuit. An input end of an eighth NAND gate circuit at an even position in the 2K numbers of eighth NAND gate circuits is coupled with a corresponding output end of the second shift register, and another input end of the eighth NAND gate circuit at the even position in the 2K numbers of eighth NAND gate circuits is coupled with the input end of the seventh NAND gate circuit An input end of a ninth NAND gate circuit is coupled with output ends of two eighth NAND gate circuits adjacent to the ninth NAND gate circuit, wherein the K numbers of ninth NAND gate circuits are coupled with different eighth NAND gate circuits, and an output end of the ninth NAND gate circuit is coupled with a corresponding row of sensors through a scanning line.

In some embodiment, the first fingerprint scanning subcircuit includes a first MOS transistor, a third shift register, N numbers of second MOS transistors, and N numbers of third MOS transistors, wherein a MOS transistor pair includes a second MOS transistor and a third MOS transistor, and N is the number of rows of sensors scanned by the first fingerprint scanning subcircuit. Agate of the first MOS transistor is coupled with a signal output end of a corresponding fingerprint detection area, a drain of the first MOS transistor is coupled with a scanning enable signal output end and a source of the first MOS transistor is coupled with the third shift register. A gate of the second MOS transistor is input with a signal obtained by inverting a fingerprint detection result signal of the corresponding fingerprint detection area, a drain of the second MOS transistor is coupled with a reset signal output end, and a source of the second MOS transistor is coupled with a source of the third MOS transistor of the MOS transistor pair. A gate of the third MOS transistor is coupled with the signal output end of the corresponding fingerprint detection area, a drain of the third MOS transistor is coupled with an output end of the third shift register, and a source of the third MOS transistor is coupled with a corresponding row of sensors through a scanning line.

In some embodiment, the second fingerprint scanning subcircuit includes: a fourth MOS transistor, a fifth MOS transistor, K numbers of sixth MOS transistors, K numbers of seventh MOS transistors, and a fourth shift register. A MOS transistor pair includes a sixth MOS transistor and a seventh MOS transistor, and K is the number of rows of sensors scanned by the second fingerprint scanning subcircuit. A gate of the fourth MOS transistor is coupled with a signal output end of a fingerprint detection area corresponding to a previous fingerprint scanning subcircuit adjacent to the second fingerprint scanning subcircuit, a drain of the fourth MOS transistor is coupled with the previous fingerprint scanning subcircuit, and a source of the fourth MOS transistor is coupled with a drain of the fifth MOS transistor. A gate of the fifth MOS transistor is coupled with the signal output end of the corresponding fingerprint detection area, and a source of the fifth MOS transistor is coupled the fourth shift register. A gate of the sixth MOS transistor is input with a signal obtained by inverting a fingerprint detection result signal of the corresponding fingerprint detection area, a drain of the sixth MOS transistor is coupled with the reset signal output end, and a source of the sixth MOS transistor is coupled with a source of the seventh MOS transistor of the MOS transistor pair. A gate of the seventh MOS transistor is coupled with the signal output end of the corresponding fingerprint detection area, a drain of the seventh MOS transistor is coupled with an output end of the third shift register, and a source of the seventh MOS transistor is coupled with a corresponding row of sensors through a scanning line.

In some embodiment, the apparatus further includes an eighth MOS transistor, wherein a gate of the eighth MOS transistor is coupled with the signal output end of the fingerprint detection area corresponding to the previous fingerprint scanning subcircuit, a drain of the eighth MOS transistor is coupled with the scanning enable signal output end, and a source of the eighth MOS transistor is coupled with the drain of the fifth MOS transistor.

In some embodiment, each of the plurality of fingerprint scanning subcircuits is disposed at one side or both sides of a corresponding row of sensors in the sensor array.

In some embodiment, any two of the plurality of fingerprint detection areas correspond to different sensors.

In some embodiment, the apparatus further includes a fingerprint identification circuit, wherein the fingerprint identification circuit is coupled with the fingerprint scanning circuit and configured to obtain a fingerprint image based on an output signal of the fingerprint scanning circuit.

In some embodiment, each fingerprint detection area corresponds to a plurality of adjacent rows of sensors in the sensor array, and the fingerprint scanning circuit is configured to scan the plurality of adjacent rows of sensors corresponding to the preset fingerprint detection area based on the detection result of the area detection circuit. The plurality of adjacent rows of sensors in the sensor array include a plurality of rows of sensors with a consecutive row number.

In some embodiment, the apparatus further includes a fingerprint capturing panel, and the fingerprint capturing panel includes the plurality of fingerprint detection areas.

In some embodiment, the fingerprint scanning subcircuit includes a plurality of fingerprint scanning sub-unit circuits, and each of the plurality of fingerprint scanning sub-unit circuits is coupled with a plurality of sensors in the sensor array through a scanning line to scan the coupled sensors.

In some embodiment, the fingerprint scanning circuit includes at least three fingerprint scanning subcircuits, and the plurality of fingerprint scanning sub-unit circuits are evenly disposed at both sides of the sensor array.

In some embodiment, the apparatus further includes a multiplexer circuit, and the multiplexer circuit is configured to select a fingerprint scanning subcircuit corresponding to a fingerprint detection area to perform scanning based on the detection result of the area detection circuit.

Another embodiment provides an electronic equipment including apparatus according to some embodiments of the present disclosure.

Compared with conventional technologies, embodiments of the present disclosure have following beneficial effects.

According to an embodiment of the present disclosure, the sensor array is divided into a plurality of fingerprint detection areas, and the fingerprint scanning circuit includes fingerprint scanning subcircuits corresponding to the fingerprint detection areas, so that the fingerprint scanning circuit can scan several sensors corresponding to the fingerprint detection area where the fingerprint is located based on the detection result of the area detection circuit. Instead of full array scanning, the power consumption of the apparatus for capturing a fingerprint can be reduced. Especially when the number of sensors in the sensor array is large, the power consumption of the apparatus can be reduced more significantly after dividing the sensor array into several fingerprint detection areas (for example, dividing the sensor array into several fingerprint detection areas in parallel arrangement parallel to the scanning line).

Furthermore, the preset fingerprint detection area also includes an adjacent detection area of the fingerprint detection area where the fingerprint is located, that is, when the fingerprint is detected, the sensors corresponding to the fingerprint detection area where the fingerprint is located are scanned, and the sensor corresponding to the adjacent detection area are also scanned. Compared with the full array scanning, the power consumption of the apparatus for capturing the fingerprint can be reduced, the integrity of fingerprint information collection can be improved, and thus the success rate of fingerprint identification can be improved.

### BRIEF DESCRIPTION OF THE DRAWINGS

FIG. 1 is schematic diagram showing a structure of an apparatus for capturing a fingerprint according to an embodiment of the present disclosure;

FIG. 2 is a schematic diagram showing positions of a fingerprint detection area and a fingerprint scanning subcircuit according to an embodiment of the present disclosure;

FIG. 3 is a schematic diagram showing an operation time sequence of the fingerprint scanning subcircuit corresponding to each fingerprint detection area in FIG. 2;

FIG. 4 is a schematic diagram showing a structure of a fingerprint scanning subcircuit according to an embodiment of the present disclosure;

FIG. 5 is a schematic diagram showing an operation time sequence of the fingerprint scanning subcircuit in FIG. 4;

FIG. 6 is a schematic diagram showing a structure of a fingerprint scanning subcircuit according to another embodiment of the present disclosure;

FIG. 7 is a schematic diagram showing a structure of an apparatus for capturing a fingerprint according to another embodiment of the present disclosure;

FIG. 8 is a schematic diagram showing a position of a fingerprint scanning subcircuit according to another embodiment of the present disclosure;

FIG. 9 is a waveform diagram of a fingerprint scanning according to an embodiment of the present disclosure; and

FIG. 10 is a schematic diagram showing a connection between a fingerprint scanning sub-unit circuit and a sensor array according to an embodiment of the present disclosure.

### DETAILED DESCRIPTION

In existing apparatus for fingerprint capturing, when the fingerprint is scanned, the sensor array in the apparatus is usually scanned in a full array, which results in a high-power consumption of the apparatus for capturing the fingerprint.

An embodiment of the present disclosure provides an apparatus for capturing a fingerprint. The sensor array in the apparatus is divided into a plurality of fingerprint detection areas, and the fingerprint scanning circuit includes fingerprint scanning subcircuits corresponding to the fingerprint detection areas, so that the fingerprint scanning circuit can scan several sensors corresponding to the fingerprint detection area where the fingerprint is located based on the detection result of the area detection circuit. Compared with full array scanning, the power consumption of the apparatus for capturing the fingerprint can be reduced.

In order to make above objects, features and beneficial effects of the present disclosure more obvious and understandable, specific embodiments of the present disclosure are described in detail in combination with the drawings.

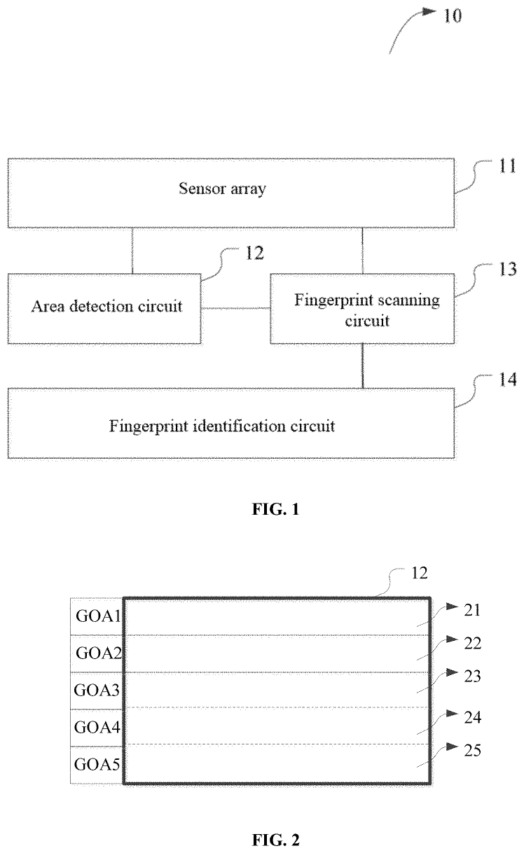

Referring to FIG. 1, an apparatus 10 for capturing a fingerprint according to an embodiment of the present disclosure is shown. The apparatus 10 may include a sensor array 11, an area detection circuit 12 and a fingerprint scanning circuit 13.

The sensor array 11 includes multiple rows and multiple columns of sensors, corresponding to multiple fingerprint detection areas, and each fingerprint detection area corresponds to a plurality of sensors in the sensor array.

The area detection circuit 12 is coupled with the sensor array 11 and configured to detect a fingerprint detection area where the fingerprint is located.

The fingerprint scanning circuit 13 is coupled with the area detection circuit 12 and the sensor array 11, and is configured to detect several (for example, several consecutive rows) of sensors corresponding to a preset fingerprint detection area based on a detection result of the area detection circuit 12. The preset fingerprint detection area includes the first fingerprint detection area where the fingerprint is located.

In some embodiment, the preset fingerprint detection area further includes an adjacent fingerprint detection area adjacent to the fingerprint detection area where the fingerprint is located. That is, when a fingerprint is detected, the sensors corresponding to the fingerprint detection area with the fingerprint are scanned, and the sensors corresponding to the adjacent fingerprint detection area are also scanned. The adjacent fingerprint detection area may include all fingerprint detection areas adjacent to the fingerprint detection area where the fingerprint is located, or a part of the all fingerprint detection areas adjacent to the fingerprint detection area where the fingerprint is located.

In some embodiment, the fingerprint scanning circuit includes a plurality of fingerprint scanning subcircuits corresponding to the plurality of fingerprint detection areas respectively, and each fingerprint scanning subcircuit is configured to scan sensors corresponding to a fingerprint detection area corresponding to each fingerprint scanning subcircuit.

In some embodiment, each fingerprint detection area corresponds to one or more rows of sensors in the sensor array. Taking the sensor array 11 consisting of M rows and N columns of sensors as an example, the sensor array corresponds to K fingerprint detection areas. Each fingerprint detection area corresponds to several adjacent rows of sensors in the sensor array, and any two fingerprint detection areas correspond to different sensors. M, N and K are all positive integers, and MK 2. The fingerprint scanning circuit 13 is configured to scan several adjacent rows of sensors corresponding to the preset fingerprint detection area based on the detection result of the area detection circuit.

In other embodiments, each fingerprint detection area may also correspond to one or more columns of sensors in the sensor array. For example, taking the sensor array 11 consisting of M rows and N columns of sensors as an example, each fingerprint detection area corresponds to K columns of sensor in the sensor array. M, N, and K are all positive integers, and N≥K≥2.

In some embodiment, the apparatus 10 for capturing the fingerprint may further include a fingerprint identification circuit 14. The fingerprint identification circuit 14 is coupled with the fingerprint scanning circuit 13 and configured to obtain a fingerprint image based on an output signal of the fingerprint scanning circuit 13. In some embodiment, the fingerprint identification circuit 14 is further configured to identify user's fingerprint based on the obtained fingerprint image.

In some embodiment, the number of rows or columns of the sensors corresponding to each fingerprint detection area may be equal or unequal, and is not limited herein. For example, each fingerprint detection area can be set to correspond to 10 adjacent rows or columns of sensors, or one fingerprint detection area can be set to correspond to 5 adjacent rows or columns of sensors, and the other fingerprint detection area can be set to correspond to 10 adjacent rows or columns of sensors.

In some embodiment, in addition to the fingerprint detection area where the fingerprint is located, the preset fingerprint detection area further includes a previous fingerprint detection area or a next fingerprint detection area or both the previous fingerprint detection area and the next fingerprint detection area.

In some embodiment, the apparatus 10 for capturing the fingerprint may further include a fingerprint capturing panel (not shown). The fingerprint capturing panel may be divided into several fingerprint detection areas. The fingerprint information is received through the fingerprint capturing panel, and then the apparatus 10 for capturing the fingerprint performs fingerprint identification on the input fingerprint information for identity verification or device unlocking.

The number of the fingerprint detection areas may be only two. At this time, the sensor array 11 is divided according to rows corresponding to two fingerprint detection areas, respectively. Certainly, the number of the fingerprint detection areas may also be 3 or more. At this time, the sensor array 11 is divided according to rows corresponding to 3 or more fingerprint detection areas, respectively.

In some embodiment, taking a sensor array with 100 rows and 1000 columns as an example, when the number of the fingerprint detection areas is two, the sensors in rows 1 to 30 may correspond to one fingerprint detection area, and the sensors in rows 31 to 100 may correspond to the other fingerprint detection area. When there are three fingerprint detection areas, i.e., a fingerprint detection area 1, a fingerprint detection area 2, and a fingerprint detection area 3, the sensors in rows 1 to 30 may correspond to the fingerprint detection area 1, the sensors in rows 31 to 60 may correspond to the fingerprint detection area 2, and the sensors in rows 61 to 100 may correspond to the fingerprint detection area 3.

In some embodiment, taking a sensor array with 100 rows and 1000 columns as an example, when the number of the fingerprint detection areas is two, the sensors in columns 1 to 500 may correspond to one fingerprint detection area, and the sensors in columns 501 to 1000 may correspond to the other fingerprint detection area. When there are three fingerprint detection areas, i.e., a fingerprint detection area 1, a fingerprint detection area 2, and a fingerprint detection area 3, the sensors in columns 1 to 300 may correspond to the fingerprint detection area 1, the sensors in columns 301 to 600 may correspond to the fingerprint detection area 2, and the sensors in columns 601 to 1000 may correspond to the fingerprint detection area 3.

In some embodiment of the present disclosure, the fingerprint scanning circuit may include a plurality of fingerprint scanning subcircuits having a one-to-one correspondence with the plurality of fingerprint detection areas. Each fingerprint scanning subcircuit is coupled with corresponding rows of sensors in the sensor array through a scanning line to scan the corresponding rows of sensors in the sensor array.

Since the fingerprint detection areas are divided according to the rows of the sensor array 11, all fingerprint scanning subcircuits can be disposed at the same side of the corresponding rows of sensors in the sensor array 11, in order to reduce crosstalk between scanning lines, as shown in FIG. 2.

In some embodiment, when a fingerprint is input on the fingerprint capturing panel, the area detection circuit 12 can detect the area where the fingerprint is located. For example, the fingerprint capturing panel may be a touch screen. When the fingerprint is input on the touch screen, the area detection circuit 12 may detect a pressure on the touch screen to determine the fingerprint detection area where the fingerprint is located. Through the area detection circuit 12, the fingerprint information is roughly detected. The area detection circuit 12 outputs a detection result signal to the fingerprint scanning circuit 13, and the fingerprint scanning circuit 13 accurately scans the fingerprint information.

In some embodiment, the area detection circuit 12 may directly output a corresponding signal to the fingerprint scanning subcircuit corresponding to the fingerprint detection area where the fingerprint is located, and trigger the fingerprint scanning subcircuit corresponding to the fingerprint detection area where the fingerprint is located to perform fingerprint scanning.

In some embodiment, in the fingerprint scanning circuit 13, the fingerprint scanning subcircuits corresponding to the preset fingerprint detection area sequentially scans the corresponding rows of sensors in the sensor array 11 in a time-division manner, and remaining fingerprint scanning subcircuits simultaneously reset remaining rows of sensors in the sensor array 11.

It can be understood that the sensors corresponding to different fingerprint detection areas are coupled with the corresponding fingerprint scanning subcircuits through different scanning lines.

In addition to the fingerprint detection area where the fingerprint is located, the fingerprint preset fingerprint detection area further includes a previous fingerprint detection area or a next fingerprint detection area or both the previous fingerprint detection area and the next fingerprint detection area.

Referring to FIG. 2, the number of the fingerprint detection areas corresponding to the sensor array 11 is 5, i.e., a fingerprint detection area 21, a fingerprint detection area 22, a fingerprint detection area 23, a fingerprint detection area 24, and a fingerprint detection area 25. The number of corresponding fingerprint scanning subcircuits is also 5, i.e., a fingerprint scanning subcircuit GOA1, a fingerprint scanning subcircuit GOA2, a fingerprint scanning subcircuit GOA3, a fingerprint scanning subcircuit GOA4 and a fingerprint scanning subcircuit GOA5.

The fingerprint scanning subcircuit GOA1 is used to scan the sensors corresponding to the fingerprint detection area 21. The fingerprint scanning subcircuit GOA2 is used to scan the sensors corresponding to the fingerprint detection area 22. The fingerprint scanning sub circuit GOA3 is used to scan the sensors corresponding to the fingerprint detection area 23. The fingerprint scanning subcircuit GOA4 is used to scan the sensors corresponding to the fingerprint detection area 24. The fingerprint scanning subcircuit GOA5 is used to scan the sensors corresponding to the fingerprint detection area 25.

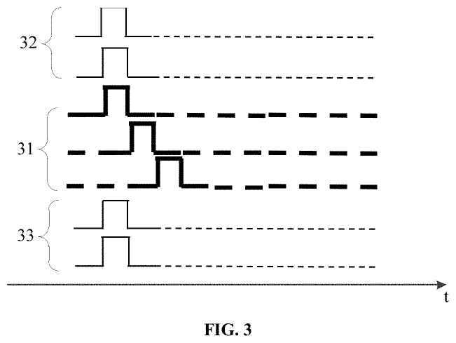

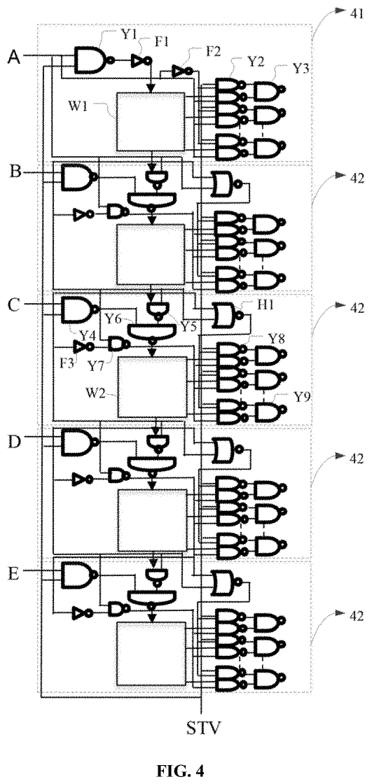

Referring to FIG. 3, when the fingerprint exists on the fingerprint detection area 23, the fingerprint scanning subcircuit GOA3 performs scanning for each row in the fingerprint detection area 23 sequentially in a time-division manner, and the fingerprint scanning subcircuit GOA4 performs scanning for each row in the fingerprint detection area 24 sequentially in a time-division manner. Corresponding sequence diagram is shown by 31, and the sequence diagrams of the fingerprint scanning subcircuit corresponding to other fingerprint detection areas are shown by 32 and 33.

In some embodiment, the fingerprint scanning subcircuits may include a first fingerprint scanning subcircuit and a second fingerprint scanning subcircuit. The first fingerprint scanning subcircuit is configured to scan the sensors corresponding to a first fingerprint detection area, and the second fingerprint scanning subcircuit is configured to scan the sensor corresponding to a remaining fingerprint detection area other than the first fingerprint detection area. The sensors corresponding to the first fingerprint detection area includes a first row of sensors in the sensor array.

Because the adjacent fingerprint detection area of the first fingerprint detection area is only the next fingerprint detection area of the first fingerprint detection area, there is no previous fingerprint detection area of the first fingerprint detection area, and the adjacent fingerprint detection area of the other fingerprint detection area other than the first fingerprint detection area may be a previous fingerprint detection area of the other fingerprint detection area, and may also be the next fingerprint detection area of the other fingerprint detection area, so different fingerprint scanning subcircuits can be set to scan different fingerprint detection areas and adjacent fingerprint detection areas.

The structures of each second fingerprint scanning subcircuit can be the same or different. The number of the second fingerprint scanning subcircuits can be only one or two or more. For example, in FIG. 4, there are four second fingerprint scanning subcircuits 42.

In some embodiment, a variety of circuit structures can be adopted to realize the first fingerprint scanning subcircuit and the second fingerprint scanning subcircuit, and are not limited herein.

In some embodiment, referring to FIG. 4, the first fingerprint scanning subcircuit 41 may include a first NAND gate circuit Y1, a first inverter F1, a second inverter F2, 2N numbers of second NAND gate circuits Y2, N numbers of third NAND gate circuits Y3 and a first shift register W1. N is the number of rows of the sensor scanned by the first fingerprint scanning subcircuit 41.

A first input end of the first NAND gate circuit Y1 is coupled with a signal output end A of a corresponding fingerprint detection area, where the signal output end is configured to output fingerprint detection result of the corresponding fingerprint detection area. A second input end of the first NAND gate circuit is coupled with a scanning enable signal output end STV, and an output end of the first NAND gate circuit is coupled with an input end of the first inverter F1.

An output end of the first inverter F1 is coupled with an input end of the first shift register W1.

An input end of the second inverter F2 is coupled with the first input end of the first NAND gate circuit Y1, and an output end of the second inverter F2 is coupled with a second NAND gate circuit at an odd position among the 2N numbers of second NAND gate circuits. An input end of the second NAND gate circuit at the odd positions among the 2N numbers of second NAND gate circuits is coupled with the scanning enable signal output end STV.

An input end of a second NAND gate circuit at an even position among the 2N numbers of second NAND gate circuits is coupled with a corresponding output end of the first shift register W1, and another input end of the second NAND gate circuit at an even position among the 2N numbers of second NAND gate circuits is coupled with the first input end of the first NAND gate circuit Y1.

Input ends of each third NAND gate circuit are coupled with output ends of two second NAND gate circuits adjacent to each third NAND gate circuit. The N numbers of third NAND gate circuits are coupled with different second NAND gate circuits, and an output end of each third NAND gate circuit is coupled with a corresponding row of sensors through a scanning line.

For example, when the number of rows of the sensors scanned by the first fingerprint scanning subcircuit 41 is 10, N=10, and the number of the second NAND gates Y2 is 20 and the number of the third NAND gates Y3 is 10. Among 20 second NAND gate circuits Y2, the 1st, 3rd, 5th, 7th, . . . , 19th second NAND gate circuits Y2 are coupled with the output end of the second inverter F2 and the scanning enable signal output end STV. Among 20 second NAND gate circuits Y2, the 2nd, 4th, 6th, 8th, . . . , and 20th second NAND gate circuits Y2 are coupled with corresponding output end of the first shift register W1 and the first input end of the first NAND gate circuit Y1.

In addition, among 20 second NAND gate circuits Y2, the output ends of the 1st and 2nd NAND gate circuits Y2 are coupled with the input end of the 1st third NAND gate circuits Y3. The output ends of the 3rd and 4th second NAND gates Y2 are coupled with the input end of the 2nd third NAND gates Y3 . . . . The output ends of the 19th and 20th second NAND gate circuit Y2 are coupled with the input end of the 10th third NAND gate circuit Y3.

In some embodiment, referring to FIG. 4, each second fingerprint scanning subcircuit in the fingerprint scanning circuit has the same structure, and each second fingerprint scanning subcircuit 42 may include a fourth NAND gate circuit Y4, a fifth NAND gate circuit Y5, a sixth NAND gate circuit Y6, a seventh NAND gate circuit Y7, a second shift register W2, a third inverter F3, a first NOR gate circuit, and 2K numbers of eighth NAND gate circuits and K numbers of ninth NAND gate circuits. K is the number of rows of sensors scanned by the second fingerprint scanning subcircuit 42.

A first input end of the fourth NAND gate circuit Y4 is coupled with a signal output end of a corresponding fingerprint detection area, such as a signal output end B, C, D, or E. A second input end of the fourth NAND gate circuit is coupled with the scanning enable signal output end STV. An output end of the fourth NAND gate circuit is coupled with an input end of the sixth NAND gate Y6.

An input end of the fifth NAND gate circuit is coupled with an output end of a shift register in a previous fingerprint scanning subcircuit adjacent to the second fingerprint scanning subcircuit, and another input end of the fifth NAND gate circuit is coupled with a signal output end of a fingerprint detection area corresponding to the previous fingerprint scanning subcircuit. For example, when the adjacent previous fingerprint scanning subcircuit is the first fingerprint scanning subcircuit 41, one input end of the fifth NAND gate circuit Y5 is coupled with the output end of the first shift register W1 of the fingerprint scanning subcircuit 41, and the other input end of the fifth NAND gate circuit Y5 is coupled with the signal output end A of the fingerprint detection area corresponding to the fingerprint scanning subcircuit 41.

In some embodiments, the previous fingerprint scanning subcircuit adjacent to the second fingerprint scanning subcircuit includes a previous fingerprint scanning subcircuit adjacent to the second fingerprint scanning subcircuit in a scanning timing sequence, or a previous fingerprint scanning subcircuit adjacent to the second fingerprint scanning subcircuit in a spatial arrangement.

Another input end of the sixth NAND gate circuit is coupled with an output end of the fifth NAND gate circuit Y5, and an output end of the sixth NAND gate circuit Y6 is coupled with an input end of the second shift register W2.

A first input end of the first NOR gate circuit H1 is coupled with the previous fingerprint scanning subcircuit, a second input end of the first NOR gate circuit H1 is coupled with an input end of the third inverter F3, and an output end of the first NOR gate circuit H1 is coupled with an eighth NAND gate circuit at an odd position among the 2K NOR gate circuits. An input end of the eighth NAND gate circuit at the odd position among the 2K eighth NAND gate circuits is coupled with the scanning enable signal output end STV. An output end of the third inverter F3 is coupled with an input end of the seventh NAND gate circuit Y7.

Specifically, when the previous fingerprint scanning subcircuit is the first fingerprint scanning subcircuit 41, the first input end of the first NOR gate H1 is coupled with the signal output end A of the fingerprint detection area corresponding to the first fingerprint detection unit 41. When the previous fingerprint scanning subcircuit is the second fingerprint scanning subcircuit 42, the first input end of the first NOR gate H1 is coupled with the input end of the third inverter F3 in the previous second fingerprint scanning subcircuit 42. The output end of the first NOR gate H1 is coupled with the 1st, 3rd, 5th, . . . , (2K−1)th eighth NAND gate circuit Y8 among the 2K numbers of eighth NAND gate circuits Y8.

An input end of an eighth NAND gate circuit Y8 at an even position among the 2K numbers of eighth NAND gate circuits Y8 is coupled with a corresponding output end of the second shift register W2. That is, among the 2K numbers of eighth NAND gate circuits Y8, input ends of the 2nd, 4th, 6th, (2K)th eighth NAND gate circuits Y8 are coupled with the corresponding output end of the second shift register W2. The other input end of the eighth NAND gate circuit Y8 at the even position among the 2K numbers of eighth NAND gate circuits Y8 is coupled with the input end of the seventh NAND gate circuit Y7.

Input ends of each ninth NAND gate circuit Y9 are coupled with output ends of two eighth NAND gate circuits Y8 adjacent to each ninth NAND gate circuit Y9. The K numbers of ninth NAND gate circuits Y9 are coupled with different eighth NAND gate circuits Y8. An output end of each ninth NAND gate circuit is coupled with a corresponding row of sensors through a scanning line.

For example, among ten eighth NAND gate circuits Y8, the output ends of the 1st and 2nd eighth NAND gate circuits Y8 are coupled with the input ends of the 1st ninth NAND gate circuit Y9. The output ends of the 3rd and 4th eighth NAND gate circuits Y8 are coupled with the input ends of the 2nd ninth NAND gate circuit Y9. The output ends of the 9th and 10th eighth NAND gate circuit Y8 are coupled with the input ends of the 9th ninth NAND gate circuit Y9.

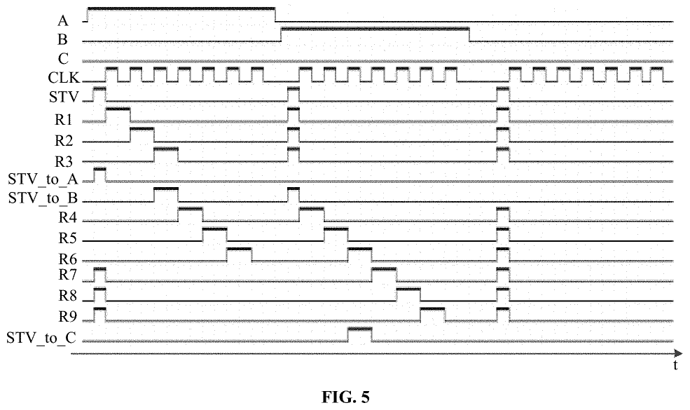

Referring to FIG. 5, it is assumed that the sensor array has 9 rows, i.e., R1 to R9 respectively. Among them, the sensors in R1 to R3 correspond to a same fingerprint detection area 1, and the signal output end corresponding to the fingerprint detection area 1 is A. The sensors in R4 to R6 correspond to a same fingerprint detection area 2, and the signal output end corresponding to the fingerprint detection area 2 is B. The sensors in R7 to R9 correspond to a same fingerprint detection area 3, and the signal output end corresponding to the fingerprint detection area 3 is C.

The first fingerprint scanning subcircuit and the second fingerprint scanning subcircuit shown in FIG. 4 are used to scan the fingerprint detection area where the fingerprint is located and the next fingerprint detection area.

When a signal output by of the scanning enable signal output end STV is high level signal, the fingerprint scanning starts. When a signal output by the signal output end A is high level signal, the fingerprint exists in the fingerprint detection area 1. In the fingerprint scanning subcircuit corresponding to the fingerprint detection area 1, the shift register receives a high-level signal STV_to_A, and the fingerprint scanning subcircuit corresponding to the fingerprint detection area 1 starts to perform fingerprint canning for the sensors in R1 to R3 sequentially in a time-division manner. In the fingerprint scanning subcircuit corresponding to the fingerprint detection area 2, the shift register receives a high-level signal STV_to_B, and the fingerprint scanning subcircuit corresponding to the fingerprint detection area 2 starts to perform fingerprint canning for the sensors in R4 to R6 sequentially in a time-division manner.

When a signal output by the signal output end B is high level signal, the fingerprint exists in the fingerprint detection area 2. In the fingerprint scanning subcircuit corresponding to the fingerprint detection area 2, the shift register receives a high-level signal STV_to_B, and the fingerprint scanning subcircuit corresponding to the fingerprint detection area 2 starts to perform fingerprint canning for the sensors in R4 to R6 sequentially in a time-division manner. In the fingerprint scanning subcircuit corresponding to the fingerprint detection area 3, the shift register receives a high-level signal STV_to_C, and the fingerprint scanning subcircuit corresponding to the fingerprint detection area 3 starts to perform fingerprint canning for the sensors in R7 to R9 sequentially in a time-division manner.

In some embodiment, the first fingerprint scanning subcircuit includes a first MOS transistor N1, a third shift register W3, N numbers of second MOS transistors N2 and N numbers of third MOS transistors N3. A MOS transistor pair includes a second MOS transistor N2 and a third MOS transistor N3. N is the number of rows of the sensors scanned by the first fingerprint scanning subcircuit.

In some embodiment of the present disclosure, in order to simplify the diagram, N=1. It should be understood that in a specific implementation, N may also be greater than or equal to 2. When N is greater than or equal to 2, there are N MOS transistor pairs composed of one second MOS transistor N2 and one third MOS transistor N3 in the first fingerprint scanning subcircuit, and each MOS transistor pair is respectively coupled with a corresponding output end of the third shift register W3.

A gate of the first MOS transistor N1 is coupled with a signal output end A of a corresponding fingerprint detection area, a drain of the first MOS transistor N1 is coupled with the scanning enable signal output end STV and a source of the first MOS transistor N1 is coupled with the third shift register W3.

A gate of the second MOS transistor N2 is input with a signal Abar obtained by inverting a fingerprint detection result signal of the corresponding fingerprint detection area, a drain of the second MOS transistor N2 is coupled with a reset signal output end GR, and a source of the second MOS transistor N2 is coupled with a source of the third MOS transistor N3 of the MOS transistor pair. The reset signal output end GR outputs a high-level signal with a constant voltage for resetting the fingerprint detection area where the fingerprint is not located, so as to prevent floating connection of the transistor coupled with the reset signal output terminal GR in the fingerprint detection area where the fingerprint is not located.

A gate of the third MOS transistor N3 is coupled with the signal output end A of the corresponding fingerprint detection area, a drain of the third MOS transistor N3 is coupled with an output end of the third shift register W3, and a source of the third MOS transistor is coupled with a corresponding row of sensors through a scanning line.

It should be noted that in some embodiment, the source of the third MOS transistor N3 may be coupled with the output end of the third shift register W3, and the drain may be coupled with the corresponding row of sensors through the scanning line. Correspondingly, the drain of the second MOS transistor N2 may be coupled with the drain of the third MOS transistor N3, and the source may be coupled with the reset signal output terminal GR.

In some embodiment of the present disclosure, the second scanning subcircuit may include a fourth MOS transistor N4, a fifth MOS transistor N5, K numbers of sixth MOS transistors N6, K numbers of seventh MOS transistors N7, and a fourth shift register W4. A MOS transistor pair includes a sixth MOS transistor N6 and a seventh MOS transistor N7. K is the number of rows of the sensors scanned by the second fingerprint scanning subcircuit.

In some embodiment of the present disclosure, in order to simplify the diagram, N=1. It should be understood that in a specific implementation, N may also be greater than or equal to 2. When N is greater than or equal to 2, there are N numbers of MOS transistor pairs composed of one sixth MOS transistor N6 and one seventh MOS transistor N7 in the second fingerprint scanning subcircuit, and each MOS transistor pair is respectively coupled with a corresponding output end of the fourth shift register W4.

A gate of the fourth MOS transistor N4 is coupled with a signal output end of the fingerprint detection area corresponding to an adjacent previous fingerprint scanning subcircuit, a drain of the fourth MOS transistor N4 is coupled with the adjacent previous fingerprint scanning subcircuit, and a source of the fourth MOS transistor N4 is coupled with a drain of the fifth MOS transistor N5.

For example, when the adjacent previous fingerprint scanning subcircuit is the first fingerprint scanning subcircuit, the gate of the fourth MOS transistor N4 is coupled with the signal output end A, and the drain is coupled with the last output end of the third shift register W3 in the first fingerprint scanning subcircuit. The last output end of the third shift register W3 is the output end of the third shift register W3 corresponding to the row of sensors finally completing fingerprint scanning in the several rows of sensors corresponding to the first fingerprint scanning subcircuit.

When the last fingerprint scanning subcircuit is the second fingerprint unit, the gate of the fourth MOS transistor N4 is coupled with the signal output terminal B, C or D. The drain is coupled with the last output end of the fourth shift register W4 in the previous second fingerprint scanning subcircuit. The last output end of the fourth shift register W4 is the output end of the fourth shift register W3 corresponding to the row of sensors finally completing fingerprint scanning in the several rows of sensors corresponding to the second fingerprint scanning subcircuit.

A gate of the fifth MOS transistor N5 is coupled with the signal output end of the corresponding fingerprint detection area, and a source of the fifth MOS transistor N5 is coupled the fourth shift register W4.

A gate of the sixth MOS transistor N6 is input with a signal obtained by inverting a fingerprint detection result signal of corresponding fingerprint detection area, a drain of the sixth MOS transistor N6 is coupled the reset signal output end GR, and a source of the sixth MOS transistor is coupled with a source of the seventh MOS transistor of the MOS transistor pair. For example, when the signal output end of the corresponding fingerprint detection area is B, a reverse signal of the fingerprint detection result signal of the corresponding fingerprint detection area is Bbar. When the signal output end of the corresponding fingerprint detection area is C, the reverse signal of the fingerprint detection result signal of the corresponding fingerprint detection area is Cbar. When the signal output end of the corresponding fingerprint detection area is D, the reverse signal of the fingerprint detection result signal of the corresponding fingerprint detection area is Dbar.

A gate of the seventh MOS transistor N7 is coupled with the signal output end of the corresponding fingerprint detection area, a drain of the seventh MOS transistor N7 is coupled with an output end of the third shift register, and a source of the seventh MOS transistor is coupled with a corresponding row of sensors through a scanning line.

The second fingerprint scanning subcircuit can be used as the last fingerprint scanning subcircuit in the fingerprint scanning circuit.

In some embodiment of the present disclosure, when the second fingerprint scanning subcircuit is not the last fingerprint scanning subcircuit in the fingerprint scanning circuit, the second fingerprint scanning subcircuit may also include an eighth MOS transistor N8. A gate of the eighth MOS transistor N8 is coupled with the signal output end of a fingerprint detection area corresponding to the adjacent previous fingerprint scanning subcircuit, a drain of the eighth MOS transistor is coupled with the scanning enable signal output end, and a source of the eighth MOS transistor is coupled with the drain of the fifth MOS transistor N5.

For example, when the adjacent previous fingerprint scanning subcircuit is the first fingerprint scanning subcircuit, the gate of the eighth MOS transistor N8 is coupled with the signal output end A. When the adjacent previous fingerprint scanning subcircuit is the second fingerprint unit, the gate of the fourth MOS transistor N4 is coupled with the signal output end B, C or D.

It should be noted that in some embodiments, the source of the fourth MOS transistor N4 may be coupled with the previous fingerprint scanning subcircuit, and the source of the eighth MOS transistor N8 may be coupled with the scanning enable signal output end STV, while the drain of the fourth MOS transistor N4 and the drain of the eighth MOS transistor N8 may be connected with the fifth MOS transistor N5, as long as the fourth MOS transistor N4 and the eighth MOS transistor N8 are disposed symmetrically.

Similarly, the source of the sixth MOS transistor N6 may be coupled with the output end of the fourth shift register W3, and the drain may be coupled with the corresponding rows of sensors through the scanning line. Correspondingly, the source of the seventh MOS transistor N7 may be coupled with the drain of the sixth MOS transistor N6, and the source of the seventh MOS transistor N7 may be coupled with reset signal output terminal GR.

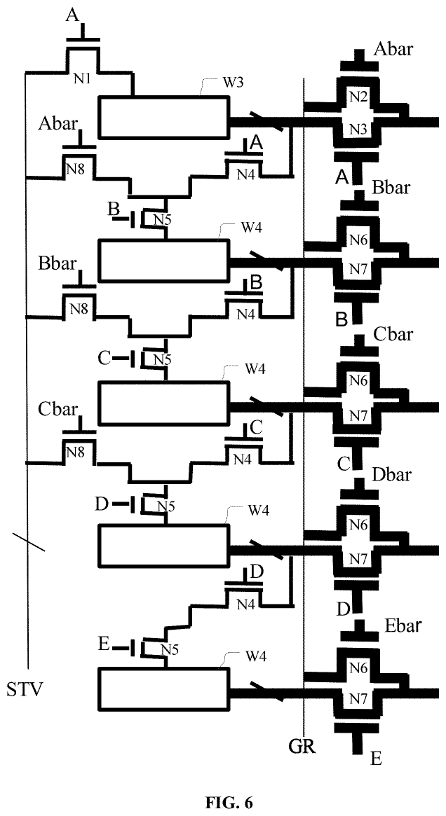

In some embodiment, by using the first fingerprint scanning subcircuit and the second fingerprint scanning sub circuit shown in FIG. 6, through the shift register in each fingerprint scanning subcircuit, the fingerprint scanning can be carried out on each row of sensors in the fingerprint detection area where the fingerprint is located and the next detection adjacent area sequentially, and the corresponding fingerprint information is collected and sent to the fingerprint identification circuit for fingerprint identification. The specific sequence diagram may be referred to FIG. 5.

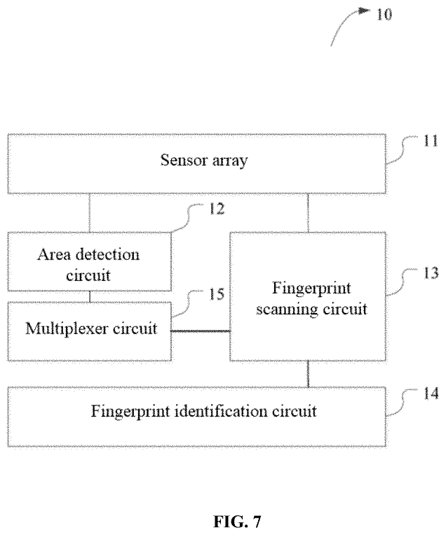

In some embodiment of the present disclosure, referring to FIG. 7, the apparatus 10 for capturing the fingerprint may also include a multiplexer circuit 15. The multiplexer circuit 15 is coupled with the area detection circuit 12 and the fingerprint scanning circuit 13, and the multiplexer circuit 15 selects a fingerprint scanning subcircuit corresponding to a fingerprint detection area to perform scanning based on the detection result output by the area detection circuit 12.

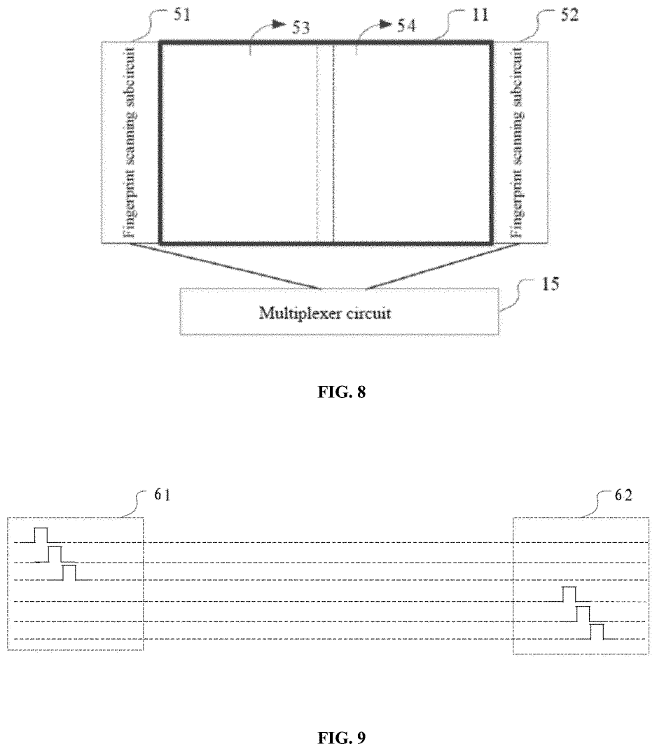

In some embodiment of the present disclosure, the fingerprint scanning circuit 13 includes two fingerprint scanning subcircuits, that is, K=2. When the sensor array only corresponds to two fingerprint detection areas, in order to reduce a crosstalk between the scanning lines, the two fingerprint scanning subcircuits can be respectively disposed at both sides of the sensor array, as shown in FIG. 8.

In another embodiment of the present disclosure, the fingerprint scanning circuit includes at least three fingerprint scanning subcircuits, that is, K>2. In order to reduce the crosstalk between the scanning lines, M numbers of fingerprint scanning sub-unit circuits of the fingerprint scanning subcircuit are evenly disposed at both sides of the sensor array.

Referring to FIG. 8, the number of the fingerprint detection areas corresponding to the sensor array 11 is two, and the number of corresponding fingerprint scanning subcircuits is also two, that is, a fingerprint scanning subcircuit 51, a fingerprint scanning subcircuit 52, a fingerprint detection area 53 and a fingerprint detection area 54. The fingerprint scanning subcircuit 51 is used to scan the sensors corresponding to the fingerprint detection area 53, and the fingerprint scanning subcircuit 52 is used to scan the sensors corresponding to the fingerprint detection area 54.

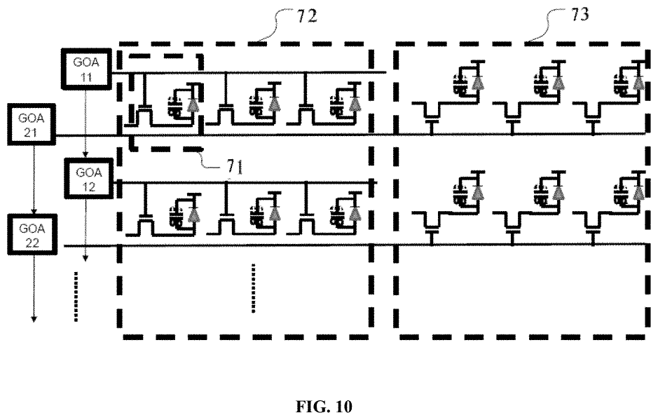

Referring to FIG. 9, for example, the sensor array 11 includes three rows of sensors. When the fingerprint exists on the fingerprint detection area 53, the multiplexer circuit 15 selects the fingerprint scanning subcircuit 54 to scan the fingerprint sequentially in a time-division manner, and the corresponding sequence diagram is shown by 61. When the fingerprint exists in the fingerprint detection area 54, the multiplexer circuit 15 selects the fingerprint scanning subcircuit 52 to scan the fingerprint sequentially in a time-division manner, and the corresponding sequence diagram is shown by 62.

In some embodiment, each fingerprint scanning subcircuit may include M fingerprint scanning sub-unit circuits in cascade connection, and each fingerprint scanning sub-unit circuit is coupled with the plurality of rows of sensors in the sensor array through the scanning line to scan the coupled sensors.

Referring to FIG. 10, in the sensor array composed of M rows of sensors 71, one fingerprint scanning subcircuit may include: a fingerprint scanning sub-unit circuit GOA11, a fingerprint scanning sub-unit circuit GOA12, . . . , a fingerprint scanning sub circuit GOA1M. Another fingerprint scanning subcircuit may include a fingerprint scanning sub-unit circuit GOA21, a fingerprint scanning sub circuit GOA22, . . . , a fingerprint scanning sub-unit circuit GOA2M. In order to simplify the illustration, the fingerprint scanning sub-unit circuit GOA1M and the fingerprint scanning sub circuit GOA2M are not shown.

The fingerprint scanning sub-unit circuit GOA11 scans the first row of sensors in the fingerprint detection area 72, the fingerprint scanning sub-unit circuit GOA12 scans the second rows of sensors in the fingerprint detection area 72, and the fingerprint scanning sub-unit circuit GOA1M scans the Mth rows of sensors in the fingerprint detection area 72.

The fingerprint scanning sub-unit circuit GOA21 scans the first row of sensors in the fingerprint detection area 73, the fingerprint scanning sub-unit circuit GOA22 scans the second rows of sensors in the fingerprint detection area 73, and the fingerprint scanning sub-unit circuit GOA2M scans the Mth rows of sensors in the fingerprint detection area 73.

If the fingerprint exists in the fingerprint detection area 72, the fingerprint scanning sub-unit circuit GOA 11 to the fingerprint scanning sub circuit GOA1M scans the corresponding rows of sensors in a time-division manner, while the fingerprint scanning sub-unit circuit GOA 21 to the fingerprint scanning sub-unit circuit GOA2M does not scan the fingerprint.

If the fingerprint exists in the fingerprint detection area 73, the fingerprint scanning sub-unit circuit GOA 21 to the fingerprint scanning sub circuit GOA2M scans the corresponding rows of sensors in a time-division manner, while the fingerprint scanning sub-unit circuit GOA 11 to the fingerprint scanning sub-unit circuit GOA1M does not scan the fingerprint.

In some embodiment, the fingerprint scanning subcircuit can realize time-division fingerprint scanning through the shift register. Specifically, each fingerprint scanning sub-unit circuit can be the shift register, and the output end of the shift register in the previous fingerprint scanning sub-unit circuit is coupled with the input end of the shift register in the next fingerprint scanning sub-unit circuit, so that the fingerprint scanning can be carried out on each row of sensors in the fingerprint detection area wherein the fingerprint is located in a time-division manner.

In some embodiment, the fingerprint detection area 72 and the fingerprint detection area 73 may be arranged in parallel in a direction parallel to the scanning line.

It can be seen from above contents that the apparatus for capturing the fingerprint of the present disclosure can effectively reduce the power consumption by dividing the sensor array into the plurality of fingerprint detection areas to scan the fingerprint detection area and/or adjacent fingerprint detection areas instead of full array scanning. Especially when the number of sensors in the sensor array is large, the power consumption of the apparatus can be reduced more significantly after dividing the sensor array into several fingerprint detection areas (for example, dividing the sensor array into several fingerprint detection areas in parallel arrangement parallel to the scanning line).

Another embodiment of the present disclosure also provides an electronic equipment. The electronic equipment includes the apparatus for capturing the fingerprint according to some embodiment of the present disclosure.

In some embodiment, the electronic equipment may be a full-screen fingerprint identification device, that is, the whole screen of the electronic equipment can be used for inputting fingerprint information. The apparatus for capturing the fingerprint can be disposed under the screen to collect the fingerprint information input on the screen and perform fingerprint identification.

In some embodiment, the electronic equipment may be a mobile phone, a tablet computer, a smart watch, a door lock, or a home appliance including a touch screen, etc.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. An apparatus for capturing a fingerprint, comprising:
a sensor array, corresponding to a plurality of fingerprint detection areas, wherein each fingerprint detection area corresponds to a plurality of sensors in the sensor array;
an area detection circuit, configured to detect a fingerprint detection area where the fingerprint is located; and
a fingerprint scanning circuit, configured to scan sensors corresponding to a preset fingerprint detection area based on a detection result of the area detection circuit, wherein the preset fingerprint detection area comprises the fingerprint detection area where the fingerprint is located.

2. The apparatus according to claim 1, wherein the preset fingerprint detection area further comprises an adjacent fingerprint detection area adjacent to the fingerprint detection area where the fingerprint is located, and the adjacent fingerprint detection area comprises all fingerprint detection areas adjacent to the fingerprint detection area where the fingerprint is located, or a part of the all fingerprint detection areas adjacent to the fingerprint detection area where the fingerprint is located.

3. The apparatus according to claim 1, wherein the fingerprint scanning circuit comprises a plurality of fingerprint scanning subcircuits corresponding to the plurality of fingerprint detection areas respectively, and each fingerprint scanning subcircuit is configured to scan sensors corresponding to a fingerprint detection area corresponding to the each fingerprint scanning subcircuit.

4. The apparatus according to claim 3, wherein each fingerprint detection area corresponds to one or more rows of sensors in the sensor array, and each fingerprint scanning subcircuit is coupled with the one or more rows of sensors in the sensor array through a scanning line to scan the one or more rows of sensors in the sensor array.

5. The apparatus according to claim 3, wherein in the fingerprint scanning circuit, one or more fingerprint scanning subcircuits corresponding to the preset fingerprint detection area are configured to scan corresponding sensors in the sensor array in a time division manner, and other fingerprint scanning subcircuits are configured to reset remaining sensors in the sensor array.

6. The apparatus according to claim 3, wherein the plurality of fingerprint scanning subcircuits comprise a first fingerprint scanning subcircuit and a second fingerprint scanning subcircuit, the first fingerprint scanning subcircuit is configured to scan sensors corresponding to a first fingerprint detection area, and the second fingerprint scanning subcircuit is configured to scan sensors corresponding to a remaining fingerprint detection area other than the first fingerprint detection area, wherein the sensors corresponding to the first fingerprint detection area comprises a first row of sensors in the sensor array.

7. The apparatus according to claim 6, wherein the first fingerprint scanning subcircuit comprises: a first NAND gate circuit, a first inverter, a second inverter, 2N numbers of second NAND gate circuits, N numbers of third NAND gate circuits and a first shift register, wherein N is the number of rows of the sensor scanned by the first fingerprint scanning subcircuit;
wherein,
a first input end of the first NAND gate circuit is coupled with a signal output end of a corresponding fingerprint detection area, a second input end of the first NAND gate circuit is coupled with a scanning enable signal output end, and an output end of the first NAND gate circuit is coupled with an input end of the first inverter;
an output end of the first inverter is coupled with an input end of the first shift register;
an input end of the second inverter is coupled with the first input end of the first NAND gate circuit, an output end of the second inverter is coupled with a second NAND gate circuit at an odd position among the 2N numbers of second NAND gate circuits, and an input end of the second NAND gate circuit at the odd position among the 2N numbers of second NAND gate circuit is coupled with the scanning enable signal output end;
an input end of a second NAND gate circuit at an even position among the 2N numbers of second NAND gate circuits is coupled with a corresponding output end of the first shift register, and another input end of the second NAND gate circuit at the even position among the 2N numbers of second NAND gate circuits is coupled with the first input end of the first NAND gate circuit; and
an input end of a third NAND gate circuit is coupled with output ends of two second NAND gate circuits adjacent to the third NAND gate circuit, wherein the N numbers of third NAND gate circuits are coupled with different second NAND gate circuits, and an output end of the third NAND gate circuit is coupled with a corresponding row of sensors through a scanning line.

8. The apparatus according to claim 7, wherein the second fingerprint scanning subcircuit comprises a fourth NAND gate circuit, a fifth NAND gate circuit, a sixth NAND gate circuit, a seventh NAND gate circuit, a second shift register, a third inverter, a first NOR gate circuit, and 2K numbers of eighth NAND gate circuits and K numbers of ninth NAND gate circuits, wherein K is the number of rows of sensors scanned by the second fingerprint scanning subcircuit;
wherein,
a first input end of the fourth NAND gate circuit is coupled with a signal output end of a corresponding fingerprint detection area, a second input end of the fourth NAND gate circuit is coupled with the scanning enable signal output end, and an output end of the fourth NAND gate circuit is coupled with an input end of the sixth NAND gate circuit;
an input end of the fifth NAND gate circuit is coupled with an output end of a shift register in a previous fingerprint scanning subcircuit adjacent to the second fingerprint scanning sub circuit, and another input end of the fifth NAND gate circuit is coupled with a signal output end of a fingerprint detection area corresponding to the previous fingerprint scanning subcircuit;
another input end of the sixth NAND gate circuit is coupled with an output end of the fifth NAND gate circuit, and an output end of the sixth NAND gate circuit is coupled with an input end of the second shift register;
a first input end of the first NOR gate circuit is coupled with the previous fingerprint scanning subcircuit, a second input end of the first NOR gate circuit is coupled with an input end of the third inverter, and an output end of the first NOR gate circuit is coupled with an eighth NAND gate circuit at an odd position among the 2K numbers of eighth NAND gate circuits;
an input end of the eighth NAND gate circuit at the odd position among the 2K numbers of eighth NAND gate circuits is coupled with the scanning enable signal output end;
an output end of the third inverter is coupled with an input end of the seventh NAND gate circuit;
an input end of an eighth NAND gate circuit at an even position in the 2K numbers of eighth NAND gate circuits is coupled with a corresponding output end of the second shift register, and another input end of the eighth NAND gate circuit at the even position in the 2K numbers of eighth NAND gate circuits is coupled with the input end of the seventh NAND gate circuit; and
an input end of a ninth NAND gate circuit is coupled with output ends of two eighth NAND gate circuits adjacent to the ninth NAND gate circuit, wherein the K numbers of ninth NAND gate circuits are coupled with different eighth NAND gate circuits, and an output end of the ninth NAND gate circuit is coupled with a corresponding row of sensors through a scanning line.

9. The apparatus according to claim 6, wherein the first fingerprint scanning subcircuit comprises a first MOS transistor, a third shift register, N numbers of second MOS transistors, and N numbers of third MOS transistors, wherein a MOS transistor pair comprises a second MOS transistor and a third MOS transistor, and N is the number of rows of sensors scanned by the first fingerprint scanning subcircuit;
wherein,
a gate of the first MOS transistor is coupled with a signal output end of a corresponding fingerprint detection area, a drain of the first MOS transistor is coupled with a scanning enable signal output end and a source of the first MOS transistor is coupled with the third shift register;
a gate of the second MOS transistor is input with a signal obtained by inverting a fingerprint detection result signal of the corresponding fingerprint detection area, a drain of the second MOS transistor is coupled with a reset signal output end, and a source of the second MOS transistor is coupled with a source of the third MOS transistor of the MOS transistor pair; and
a gate of the third MOS transistor is coupled with the signal output end of the corresponding fingerprint detection area, a drain of the third MOS transistor is coupled with an output end of the third shift register, and a source of the third MOS transistor is coupled with a corresponding row of sensors through a scanning line.

10. The apparatus according to claim 9, wherein the second fingerprint scanning subcircuit comprises: a fourth MOS transistor, a fifth MOS transistor, K numbers of sixth MOS transistors, K numbers of seventh MOS transistors, and a fourth shift register, wherein a MOS transistor pair comprises a sixth MOS transistor and a seventh MOS transistor, and K is the number of rows of sensors scanned by the second fingerprint scanning subcircuit;
a gate of the fourth MOS transistor is coupled with a signal output end of a fingerprint detection area corresponding to a previous fingerprint scanning subcircuit adjacent to the second fingerprint scanning subcircuit, a drain of the fourth MOS transistor is coupled with the previous fingerprint scanning subcircuit, and a source of the fourth MOS transistor is coupled with a drain of the fifth MOS transistor;
a gate of the fifth MOS transistor is coupled with the signal output end of the corresponding fingerprint detection area, and a source of the fifth MOS transistor is coupled the fourth shift register;
a gate of the sixth MOS transistor is input with a signal obtained by inverting a fingerprint detection result signal of the corresponding fingerprint detection area, a drain of the sixth MOS transistor is coupled with the reset signal output end, and a source of the sixth MOS transistor is coupled with a source of the seventh MOS transistor of the MOS transistor pair; and
a gate of the seventh MOS transistor is coupled with the signal output end of the corresponding fingerprint detection area, a drain of the seventh MOS transistor is coupled with an output end of the third shift register, and a source of the seventh MOS transistor is coupled with a corresponding row of sensors through a scanning line.

11. The apparatus according to claim 10, further comprising an eighth MOS transistor, wherein a gate of the eighth MOS transistor is coupled with the signal output end of the fingerprint detection area corresponding to the previous fingerprint scanning subcircuit, a drain of the eighth MOS transistor is coupled with the scanning enable signal output end, and a source of the eighth MOS transistor is coupled with the drain of the fifth MOS transistor.

12. The apparatus according to claim 4, wherein each of the plurality of fingerprint scanning subcircuits is disposed at one side or both sides of a corresponding row of sensors in the sensor array.

13. The apparatus according to claim 1, wherein any two of the plurality of fingerprint detection areas correspond to different sensors.

14. The apparatus according to claim 1, further comprising a fingerprint identification circuit, wherein the fingerprint identification circuit is coupled with the fingerprint scanning circuit and configured to obtain a fingerprint image based on an output signal of the fingerprint scanning circuit.

15. The apparatus according to claim 4, wherein each fingerprint detection area corresponds to a plurality of adjacent rows of sensors in the sensor array, and the fingerprint scanning circuit is configured to scan the plurality of adjacent rows of sensors corresponding to the preset fingerprint detection area based on the detection result of the area detection circuit.

16. The apparatus according to claim 1, further comprising a fingerprint capturing panel, wherein the fingerprint capturing panel comprises the plurality of fingerprint detection areas.

17. The apparatus according to claim 5, wherein the fingerprint scanning subcircuit comprises a plurality of fingerprint scanning sub-unit circuits, and each of the plurality of fingerprint scanning sub-unit circuits is coupled with a plurality of sensors in the sensor array through a scanning line to scan the coupled sensors.

18. The apparatus according to claim 17, wherein the fingerprint scanning circuit comprises at least three fingerprint scanning subcircuits, and the plurality of fingerprint scanning sub-unit circuits are evenly disposed at both sides of the sensor array.

19. The apparatus according to claim 2, further comprising a multiplexer circuit, wherein the multiplexer circuit is configured to select a fingerprint scanning subcircuit corresponding to a fingerprint detection area to perform scanning based on the detection result of the area detection circuit.

20. An electronic equipment, comprising the apparatus for capturing a fingerprint according to claim 1.
